(19) United States
(12) Patent Application Publication
(10) Pub. No.: US 2013/0137580 A1
(43) Pub. Date: May 30, 2013

(54) SUBSTRATE FOR SUPERCONDUCTING THIN FILM, SUPERCONDUCTING THIN FILM, AND METHOD OF PRODUCING SUPERCONDUCTING THIN FILM

(71) Applicants: Yuko Hayase, Tokyo (JP); Hiroyuki Fukushima, Tokyo (JP); Yoshikazu Okuno, Tokyo (JP); Eiji Kojima, Tokyo (JP); Hisaki Sakamoto, Tokyo (JP)

(72) Inventors: Yuko Hayase, Tokyo (JP); Hiroyuki Fukushima, Tokyo (JP); Yoshikazu Okuno, Tokyo (JP); Eiji Kojima, Tokyo (JP); Hisaki Sakamoto, Tokyo (JP)

(73) Assignee: FURUKAWA ELECTRIC CO., LTD., Tokyo (JP)

(21) Appl. No.: 13/814,580

(22) PCT Filed: Jul. 25, 2012
(86) PCT No.: PCT/JP12/68873

§ 371 Date: Feb. 6, 2013

(30) Foreign Application Priority Data
Jul. 25, 2011 (JP) 2011-162331

(51) Int. Cl. H01L 39/12; H01L 39/24

(52) U.S. Cl. CPC H01L 39/125; H01L 39/24
USPC 505/237; 505/239; 505/470; 427/595; 428/471; 428/336; 428/472.2

(57) ABSTRACT

An effect of suppressing diffusion of metal elements from a substrate is high and orientation of a forcibly-oriented layer is improved. A base material (2) for a superconducting thin film includes: a substrate (10) including a metal element; a bed layer (22) formed on a surface of the substrate (10), the bed layer (22) including, as a main component, a non-orientated spinel compound that has a spinel type crystal structure and includes at least one transition metal element, Mg, and oxygen; and a forcibly-oriented layer (24) formed on a surface of the bed layer (22), the forcibly-oriented layer (24) having biaxial orientation and including, as a main component, a rock salt type compound that has a rock salt type crystal structure and includes Mg.

### TECHNICAL FIELD

The present invention relates to a base material for a superconducting thin film, a superconducting thin film, and a method for producing the superconducting thin film.

### BACKGROUND ART

A superconducting wire has been produced in which an intermediate layer is formed on a substrate, and a superconducting layer formed from an oxide superconductor showing a superconducting phenomenon at the temperature of liquid nitrogen (77 K) or higher is further formed on the intermediate layer.

In such a superconducting wire, superconducting characteristics depend greatly on the crystal orientation of the oxide superconductor, particularly, the biaxial orientation. In addition, it is necessary to improve the crystal orientation of a surface of the underlying intermediate layer in order to obtain a superconducting layer having a high biaxial orientation.

Therefore, Patent Document 1 (Japanese Patent Application Laid-Open (JP-A) No. 2011-9106) discloses a technology in which, in order to improve the crystal orientation of the surface of the intermediate layer, a lower layer called a bed layer is first formed on a metal substrate, and then a film of a material such as MgO is formed, for example, by an ion beam assisted method (IBAD method: Ion Beam Assisted Deposition) to form a forcibly-oriented layer having high c-axis orientation and a-axis in-plane orientation (these two kinds of orientation are collectively referred to as biaxial orientation).

In addition, after obtaining the forcibly-oriented layer, a cap layer formed from CeO₂ or PrO₂ is formed on the forcibly-oriented layer in order to further improve the biaxial orientation of the surface of the intermediate layer. In addition, when a superconducting layer is formed on the cap layer, a superconducting wire having satisfactory superconducting characteristics may be obtained.

At this time, it is necessary for the bed layer to have a function of suppressing diffusion of metal elements from the metal substrate or a function of increasing orientation of the forcibly-oriented layer that is formed using the IBAD method. It is general to adopt Al₂O₃/Y₂O₃ or GZO as the bed layer so as to realize these functions.

In addition, Patent Document 2 (Japanese Patent No. 2641865) discloses a technology in which a film of a spinel compound such as MgAl₂O₃ is formed on a silicon single crystal substrate by epitaxial growth, an MgO film is further formed by epitaxial growth, and then a superconducting layer is formed.

### DISCLOSURE OF INVENTION

### Technical Problem

However, since Al₂O₃ has a superior diffusion-prevention function, the film thickness thereof may be small, but since Al₂O₃ has an inferior function of increasing orientation of the forcibly-oriented layer, it is necessary to form a Y₂O₃ layer that increases the orientation. In addition, one GZO layer is capable of preventing diffusion and increasing the orientation of the forcibly-oriented layer, but since the diffusion prevention function is inferior, it is necessary to make the film thickness thereof large. Al₂O₃/Y₂O₃ and GZO each become a cause of cost increase. In addition, Patent Document 1 discloses a method in which ZrO₂/Y₂O₃ is used for the bed layer, but ZrO₂/Y₂O₃ does not have diffusion prevention capability. Accordingly, it is necessary to form a film of a material having a diffusion prevention capability as a lower layer.

In addition, in a configuration of Patent Document 2, since the single crystal base plate is used, and the film of the spinel compound is formed by epitaxial growth, an underlying layer of the MgO film is an oriented layer formed from the spinel compound, and thus the IBAD method may not be used as means for forming the MgO film. In addition, when another way (for example, epitaxial growth) other than the IBAD method is used, the MgO film that is formed does not become a layer having biaxial orientation.

The invention has been made in consideration of the above-described circumstances, and an object thereof is to provide a base material for a superconducting thin film, which has a configuration in which an effect of suppressing diffusion of metal elements from a substrate is high and which is capable of improving orientation of a forcibly-oriented layer, a superconducting thin film, and a method for producing the superconducting thin film.

### Solution to Problem

The above-described object of the invention has been achieved by the following means.

<1> A base material for a superconducting thin film, the base material comprising:

a substrate including a metal element;

a bed layer formed on a surface of the substrate, the bed layer including, as a main component, a non-orientated spinel compound that has a spinel type crystal structure and includes at least one transition metal element, Mg, and oxygen; and

a forcibly-oriented layer formed on a surface of the bed layer, the forcibly-oriented layer having biaxial orientation and including, as a main component, a rock salt type compound that has a rock salt type crystal structure and includes Mg.

<2> A base material for a superconducting thin film, the base material comprising:

a substrate including a metal element;

a bed layer formed on a surface of the substrate, the bed layer including, as a main component, a non-orientated spinel compound that has a spinel type crystal structure and includes at least one transition metal element, Ba, and oxygen; and

a forcibly-oriented layer formed on a surface of the bed layer, the forcibly-oriented layer having biaxial orientation and including, as a main component, a rock salt type compound that has a rock salt type crystal structure and includes Ba.

<3> The base material for a superconducting thin film according to <1>, wherein the spinel compound is at least one of MgAl₂O₄, MgCr₂O₄, MgY₂O₄, MgLa₂O₄, or MgGd₂O₄.

<4> The base material for a superconducting thin film according to any one of <1> to <3>, wherein a thickness of the bed layer is from 10 nm to 500 nm.

<5> The base material for a superconducting thin film according to any one of <1> to <4>, wherein the metal element of the substrate is Ni or Fe.

<6> A superconducting thin film, comprising:

the base material for a superconducting thin film according to any one of <1> to <5>; and

a superconducting layer that is formed on a surface of the forcibly-oriented layer of the base material for a superconducting thin film and includes an oxide superconductor.

<7> A method for producing a base material for a superconducting thin film, the method comprising:

a step of forming a bed layer on a surface of a substrate including a metal element, the bed layer including a non-orientated spinel compound that has a spinel type crystal structure and includes one transition metal and Mg; and

a step of forming a forcibly-oriented layer on a surface of the bed layer using an ion beam assisted method, the forcibly-oriented layer having biaxial orientation and including, as a main component, a rock salt type compound that has a rock salt type crystal structure and includes Mg.

<8> A method for producing a base material for a superconducting thin film, the method comprising:

a step of forming a bed layer directly on a substrate including a metal element, the bed layer including a non-orientated spinel compound that has a spinel type crystal structure and includes one transition metal and Ba; and

a step of forming a forcibly-oriented layer on a surface of the bed layer using an ion beam assisted method, the forcibly-oriented layer having biaxial orientation and including, as a main component, a rock salt type compound that has a rock salt type crystal structure and includes Ba.

### Advantageous Effects of Invention

According to the invention, there have been provided a base material for a superconducting thin film, which has a configuration in which an effect of suppressing diffusion of metal elements from a substrate is high and which is capable of improving orientation of a forcibly-oriented layer, a superconducting thin film, and a method for producing the superconducting thin film.

### BRIEF DESCRIPTION OF DRAWINGS

FIG. 1 is a diagram illustrating a layered structure of a superconducting thin film according to an embodiment of the invention.

FIG. 2 is a cross-sectional diagram illustrating a detailed configuration of a base material for a superconducting wire according to the embodiment of the invention.

### BEST MODE FOR CARRYING OUT THE INVENTION

Hereinafter, a base material for a superconducting thin film, a superconducting thin film, and a method for producing the superconducting thin film according to an embodiment of the invention will be specifically described with reference to the attached drawings. In addition, in the drawings, the same reference numerals are given to members (constituent elements) having the same or corresponding functions, and description thereof will be appropriately omitted.

<Schematic Configuration of Superconducting Thin Film>

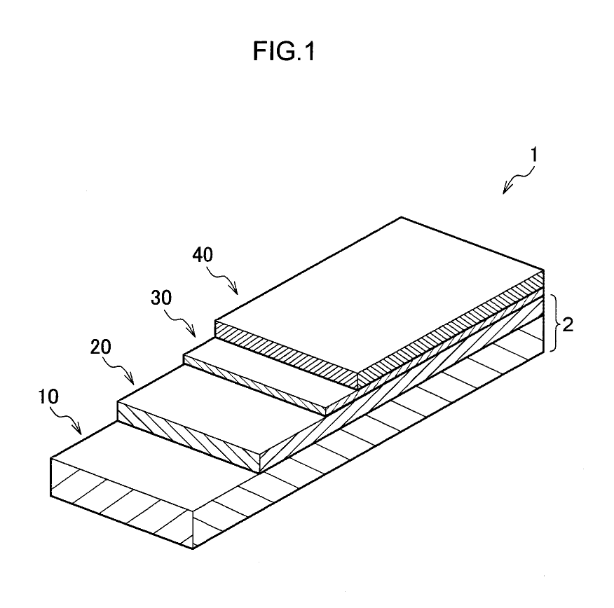

FIG. 1 shows a diagram illustrating a layered structure of a superconducting thin film 1 according to the embodiment of the invention.

As shown in FIG. 1, the superconducting thin film 1 has a layered structure in which an intermediate layer 20, a superconducting layer 30, and a protective layer 40 are sequentially formed on a substrate 10. In addition, in FIG. 1, the tape-shaped substrate 10 and the intermediate layer 20 make up a base material 2 for a superconducting wire according to the embodiment.

The substrate 10 is a substrate including a metal element that diffuses to the diffusion suppressing layer 20 side.

Other constituent elements may be included in the substrate 10, but it is preferable that the substrate 10 be a low-magnetic and non-orientated metallic substrate including only single kind or plural kinds of metal elements. As a material of the substrate 10, for example, metals such as Cu, Ni, Ti, Mo, Nb, Ta, W, Mn, Fe, and Ag that are excellent in strength and heat resistance, and alloys thereof may be used. Among these, it is preferable to use a metal such as Fe or Ni, or an alloy thereof from the viewpoint of superior corrosion resistance. In addition, examples of more preferable materials include stainless steel, and a Ni-based alloy such as Hastelloy (registered trademark) that are excellent in corrosion resistance and heat resistance. In addition, various kinds of ceramics may be disposed on these metallic materials.

The shape of the substrate 10 is not particularly limited, and materials having various shapes such as a plate material, a wire material, and a strip material may be used. For example, when a long substrate is used, the superconducting thin film 1 may be applied as a superconducting wire, and when a tape-shaped substrate is used, the superconducting thin film 1 may be applied as a superconducting tape.

The intermediate layer 20 is a layer that is formed on the substrate 10 to realize a high in-plane orientation in the superconducting layer 30. The physical characteristic values thereof, such as the coefficient of thermal expansion and the lattice constant, show intermediate values between values of the substrate 10 and values of the oxide superconductor making up the superconducting layer 30. In addition, a specific layer configuration will be described later.

The superconducting layer 30 is formed on the intermediate layer 20 and is preferably formed from an oxide superconductor, particularly, a copper oxide superconductor. As the copper oxide superconductor, a crystalline material, which is expressed by a compositional formula such as REBa₂Cu₃O_{7-δ} (referred to as RE-123), Bi₂Sr₂CaCu₂O_{8+δ} (also including one in which a Bi site is doped with Pb), Bi₂Sr₂Ca₂Cu₃O_{10+δ} (also including one in which a Bi site is doped with Pb), (La, Ba)₂CuO_{4-δ}, (Ca, Sr)CuO_{2-δ}[a Ca site may be Ba], (Nd, Ce)₂CuO₄₋₅, (Cu, Mo)Sr₂(Ce, Y)ₛCu₂O [referred to as (Cu, Mo)-12s2, and s=1, 2, 3, or 4], Ba(Pb, Bi)O₃, or Tl₂Ba₂Caₙ₋₁CuₙO₂ₙ₊₄ (n is an integer of two or more), may be used. In addition, the copper oxide superconductor may be configured by combining these crystalline materials.

Among these crystalline materials, due to the reason that superconducting characteristics are good and a crystal structure is simple, it is preferable to use REBa₂Cu₃O_{7-δ}. In addition, the crystalline material may be a polycrystalline material or a single crystalline material.

In REBa₂Cu₃O_{7-δ}, RE is a single or plural rare-earth elements such as Y, Nd, Sm, Eu, Gd, Dy, Ho, Er, Tm, Yb, and Lu, and among these, Y is preferable from the viewpoint that substitution with a Ba site is not likely to occur. In addition, δ represents a non-stoichiometric amount of oxygen, and for example, δ is from 0 to 1. It is preferable that δ be close to 0 from the viewpoint that a superconducting transition temperature is high. In addition, in regard to the non-stoichiometric amount of oxygen, when a high-pressure oxygen annealing or the like is performed by using a device such as an autoclave, 6 may be less than 0, that is, a negative value.

In addition, δ of a crystalline material other than REBa₂Cu₃O_{7-δ} also represents a non-stoichiometric amount of oxygen, and for example, 6 is from 0 to 1.

Although not particularly limited, for example, the film thickness of the superconducting layer 30 is from 500 to 3,000 nm.

Examples of a method for forming (film-forming) the superconducting layer 30 include a TFA-MOD (Metal Organic Deposition using TriFluoroAcetates) method, a PLD (Pulse Laser Deposition) method, a CVD (Chemical Vapor Deposition) method, an MOCVD (Metal Organic Chemical Vapor Deposition) method, a sputtering method, and the like. Among these film forming methods, it is preferable to use the MOCVD method due to the reason that a high vacuum is not necessary, a film may be formed on the substrate 10 having a large area or a complicated shape, and mass productivity is excellent.

A protective layer 40 formed from silver is formed on an upper surface of the above-described superconducting layer 30, for example, by a sputtering method. In addition, after the superconducting thin film 1 is produced by forming the protective layer 40, a heat treatment may be performed with respect to the superconducting thin film 1.

<Base Material for Superconducting Thin Film and Method for Production Thereof>

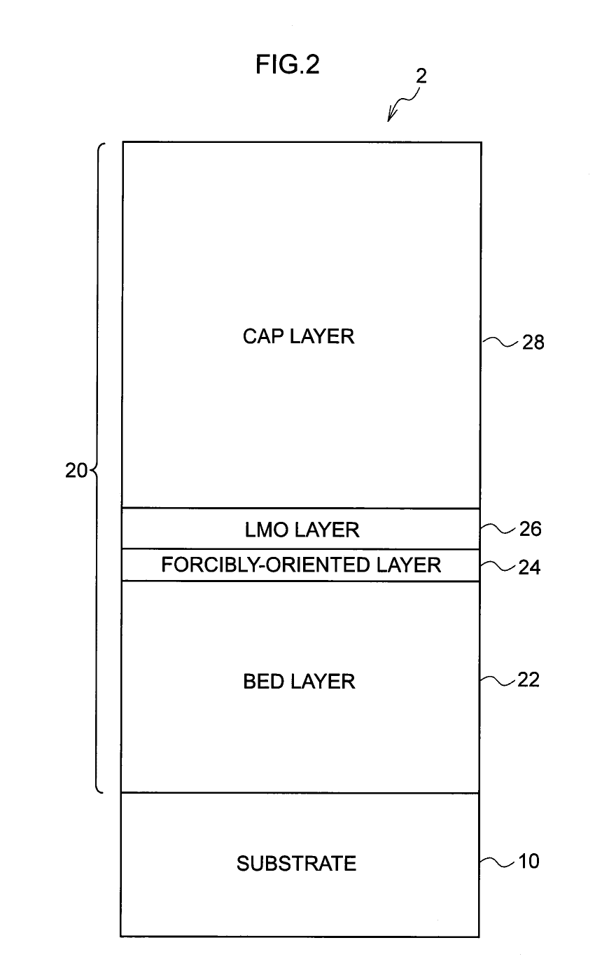

FIG. 2 shows a cross-sectional diagram illustrating a detailed configuration of the base material 2 for a superconducting wire according to the embodiment of the invention.

As shown in FIG. 2, the intermediate layer 20 of the base material 2 for the superconducting wire has a configuration in which a bed layer 22, a forcibly-oriented layer 24, an LMO layer 26, and a cap layer 28 are sequentially layered.

The bed layer 22 is a layer that is formed on the substrate 10 (on a surface of the substrate 10), suppresses diffusion of metal elements of the substrate 10, and improves a biaxial orientation of the forcibly-oriented layer 24. In addition, the embodiment is characterized in the bed layer 22, and the bed layer 22 is a layer including, as a main component, a non-orientated spinel compound that has a spinel type crystal structure and includes at least one transition metal element, Mg or Ba, and oxygen. When the bed layer 22 is configured as described above, an effect of suppressing diffusion of metal elements from the substrate 10 is high, and orientation of the forcibly-oriented layer 24 is improved. In addition, the “non-orientated” represents that each axis of more than 50% of the spinel compound of the bed layer 22 is not oriented. In addition, the “main component” represents a component having the largest content among constituent components contained in the bed layer 22.

The spinel compound is an oxide expressed by a compositional formula of AB₂O₄, and has two sites of A site and B site in a crystal. In regard to respective metal elements that occupy the A site and the B site of the oxide of the spinel structure, either Mg or Ba is selected for the A site, and at least one transition metal is selected for the B site. In addition, the “at least one” in regard to the transition metal used in the B site means that the B site may be substituted with another transition metal element. In addition, to suppress reaction between the bed layer 22 and the forcibly-oriented layer 24, a rock salt type compound of the forcibly-oriented layer 24 includes the same metal element as the A site of the spinel compound.

Specific examples of the spinel compound include at least one of MgAl₂O₄, MgCr₂O₄, MgY₂O₄, MgLa₂O₄, MgGd₂O₄, and BaAl₂O₄. Among these, in a case of using MgO in the forcibly-oriented layer 24, it is preferable that the spinel compound be at least one of MgAl₂O₄, MgCr₂O₄, MgY₂O₄, MgLa₂O₄, and MgGd₂O₄. This is because since Mg that is the same as the A site of the spinel compound is included, it is difficult for the bed layer 22 and the forcibly-oriented layer 24 to react to each other, and the spinel compound may be stably present as a compound. Furthermore, MgAl₂O₄ is more preferable from the viewpoint of practicality.

Although not particularly limited, it is preferable that a thickness of the bed layer 22 be 10 nm or more from the viewpoint of suppressing a decrease in function (a function of suppressing of diffusion of metal elements from the substrate 10 and a function of improving orientation of the forcibly-oriented layer) of the bed layer 22, and it is preferable that the thickness be 500 nm or less from the viewpoint of suppressing warping of the substrate 10. Particularly, it is preferable the thickness be 100 nm or less from a viewpoint of making the thickness small according to request of cost or the like.

Examples of a method for forming (film-forming) the bed layer 22 include a TFA-MOD method, a PLD method, a CVD method, an MOCVD method, a sputtering method, and the like. Among these, it is preferable to use the sputtering method from a viewpoint of easiness of production.

In a case of using the sputtering method, an inert gas ion (for example, Ar⁺) that is generated due to plasma discharge is made to collide with a vapor deposition source (spinel compound), and a vapor deposition particle that is ejected is deposited on a film formation surface to form a film. A film formation condition at this time is appropriately set in accordance with a constituent material, the film thickness, or the like of the bed layer 22. However, for example, the RF sputtering output is set to from 100 to 500 W, a wire material conveyance speed is set to from 10 to 100 m/h, and a film formation temperature is set to from 20 to 500° C.

The forcibly-oriented layer 24 is a layer having biaxial orientation, which is formed directly on the bed layer 22 (on a surface of the bed layer 22) and includes, as a main component, a rock salt type compound having a rock salt type crystal structure. In addition, “having biaxial orientation” represents that c-axis orientation and a-axis in-plane orientation are high, and also includes not only a case in which the a-axis and the c-axis of the entirety of the rock salt type compound are oriented, but also a case in which the a-axis and the c-axis of 90% or more of the rock salt type compound of the bed layer 22 are oriented. In addition, the meaning of “having orientation” also includes not only a case in which the c-axes and the a-axes are arranged in completely the same direction, respectively, but also a case in which the c-axes and the a-axes are arranged at angle within ±5°, respectively. In addition, the “main component” represents a component having the largest content among constituent components included in the forcibly-oriented layer 24.

In regard to the rock salt type compound of the forcibly-oriented layer 24, since it is necessary to select a metal element that does not cause the rock salt type compound of the forcibly-oriented layer 24 and the spinel compound of the bed layer 22 to chemically react with each other, the rock salt type compound includes Mg or Ba that is contained in the spinel compound of the bed layer 22 from a viewpoint that the chemical reaction is reliably suppressed.

Specifically, examples of the rock salt type compound include at least one of MgO and BaO. MgO is more preferable from a viewpoint of practicality. In addition, for example, like (Mg, Ni)O or the like, a part of cation sites may be substituted with another metal element.

Although not particularly limited, for example, the film thickness of the forcibly-oriented layer 24 is from 1 to 20 nm.

Examples of a method for forming (film-forming) the forcibly-oriented layer 24 include a method of forming a film using an IBAD method under an atmosphere of argon or oxygen, or a mixed gas atmosphere of argon and oxygen. In the IBAD method, while an assisting ion beam is emitted to a film formation surface from an oblique direction, a vapor deposition particle ejected from a vapor deposition source (MgO or the like) by RF sputtering (or ion beam sputtering) is deposited on the film formation surface to form a film. The film formation conditions at this time are appropriately set in accordance with the constituent material, the film thickness, or the like of the forcibly-oriented layer 24. However, for example, the assist ion beam voltage may be set to from 800 to 1,500 V, the assist ion beam current may be set to from 80 to 350 mA, the assist ion beam acceleration voltage may be set to 200 V, the RF sputtering output may be set to from 800 to 1,500 W, a conveyance speed of the wire material may be set to from 40 to 500 m/h, and a film formation temperature may be set to from 5 to 350° C.

The term “forcibly-oriented layer” represents a layer that is formed by the IBAD method and has biaxial orientation, and whether or not the layer is the forcibly-oriented layer formed by the IBAD method may be specified by analyzing whether or not the bed layer 22 is non-oriented and whether or not a layer to be the forcibly-oriented layer 24 has biaxial orientation by X-ray diffraction measurement.

The LMO layer 26 is disposed between the forcibly-oriented layer 24 and the cap layer 28 and has a function of improving a lattice matching property of the cap layer 28. The LMO layer 26 is an oxide layer formed from a crystalline material having a compositional formula expressed by LaMnMO_{3+δ} (δ is a non-stoichiometric amount of oxygen). In addition, although not particularly limited, for example, a value of 6 is within a range of −1<δ<1. In addition, it is preferable that the LMO layer 26 be an oxide layer formed from a crystalline material having a compositional formula expressed by La_{z}(Mn₁₋ₓMₓ)_{w}O_{3+δ} (M is at least one selected from Cr, Al, Co, and Ti, δ represents a non-stoichiometric amount of oxygen, 0<z/w<2, and 0<x≦1) from a viewpoint of lowering a phase transition temperature at which a crystalline lattice of LMO becomes a cubic.

Although not particularly limited, it is preferable that the thickness of the LMO layer 26 be 100 nm or less from a viewpoint of suppressing surface defects of the LMO layer 26, and it is preferably 4 nm or more from a production viewpoint. As a specific value, 30 nm may be exemplified.

Examples of a method for forming (film-forming) the LMO layer 26 include a film formation in accordance with an RF sputtering method or a PLD method which is carried out while heating the substrate 10. The film formation conditions in accordance with the RF sputtering method may be appropriately set in accordance with a substitution amount x of M in La_{z}(Mn₁₋ₓMₓ)_{w}O_{3+δ} that is a constituent material of the LMO layer 26, the film thickness of the LMO layer 26, or the like. For example, the sputtering output may be set to from 100 to 300 W, the wire material conveyance speed may be set to from 20 to 200 m/h, the film formation temperature (substrate heating temperature) may be set to 800° C. or lower, and the film formation atmosphere may be set to from 0.1 to 1.5 Pa of an Ar gas atmosphere.

The cap layer 28 is a layer that is formed on the LMO layer 26 to protect the LMO layer 26, and further increases a lattice matching property with the superconducting layer 30. Specifically, the cap layer 28 is configured by a fluorite-type crystal structure that contains a rare-earth element and has self-orientation. For example, the fluorite-type crystal structure is at least one selected from CeO₂ and PrO₂. In addition, the cap layer 28 may mainly contain the fluorite-type crystal structure, and may further contain impurities.

Although not particularly limited, it is preferable that the film thickness of the cap layer 28 be 50 nm or more to obtain sufficient orientation, and more preferably 300 nm or more. However, when exceeding 600 nm, a film formation time increases, and thus it is preferable that the thickness be set to 600 nm or less.

Examples of a method for forming (film-forming) the cap layer 28 include a film formation in accordance with a PLD method or an RF sputtering method. A film formation condition in accordance with the RF sputtering method may be appropriately set in accordance with a constituent material, a film thickness, or the like of the cap layer 28. For example, an RF sputtering output may be set to from 200 to 1,000 W, a wire material conveyance speed may be set to from 2 to 50 m/h, and a film formation temperature may be set to from 450 to 800° C.

<Effects>

As described above, in the embodiment, the bed layer 22 that is configured by a spinel compound having a spinel type crystal structure and including at least one transition metal element, Mg or Ba, and oxygen is provided as an underlying layer of the forcibly-oriented layer 24 that is configured by a rock salt type compound having a rock salt type crystal structure and has biaxial orientation, and the spinel compound and the rock salt type compound include the same metal element (Mg or Ba). Accordingly, due to crystal stability of the spinel type crystal structure, reaction between the spinel compound and the rock salt type compound is suppressed, and the rock salt type compound of the forcibly-oriented layer 24 and the spinel compound of the bed layer 22 do not chemically react with each other. As a result, orientation of the forcibly-oriented layer 24 may be improved. In addition, when the orientation of the forcibly-oriented layer 24 can be increased, the orientation of the superconducting layer 30, which is formed as an upper layer, may be increased, and thus a critical current characteristic of the superconducting thin film 1 may be improved.

### Modification Examples

In addition, the specific embodiment of the invention has been described in detail, but the invention is not limited to the embodiment, and it will be apparent to a person having ordinary skill in the art that various different embodiments are possible within a scope of the invention. For example, the above-described plural embodiments may be appropriately carried out in combination. In addition, the following modification examples may be appropriately combined.

For example, the LMO layer 26, the cap layer 28, or the protective layer 40 may be omitted. In addition, instead of the LMO layer 26, another layer may be added to the intermediate layer 20.

In addition, in the embodiment, description has been made with respect to a case in which the bed layer 22 is formed using the spinel compound as a target, but for example, the bed layer 22 of the spinel compound may be formed by forming a film of Al₂O₃ and then forming a film of MgO on the Al₂O₃ under an appropriate condition. The bed layer 22 of the spinel compound may also be formed by performing a high-temperature heat treatment or ion beam irradiation.

In addition, in the embodiment, description has been made with respect to the superconducting thin film 1, but the superconducting thin film 1 may be applied to various other devices. For example, the superconducting thin film 1 may be applied to a device such as a superconducting current limiter, an SMES (Superconducting Magnetic Energy Storage), a superconducting transformer, an NMR (Nuclear Magnetic Resonance) analyzing device, a single crystal pulling up device, a linear motor car, and a magnetic separator.

In addition, the disclosure of Japanese Patent Application No. 2011-162331 is incorporated herein by reference in its entirety.

All publications, patent applications, and technical standards mentioned in this specification are herein incorporated by reference to the same extent as if each individual publication, patent application, or technical standard was specifically and individually indicated to be incorporated by reference.

### EXAMPLES

Hereinafter, a base material for a superconducting thin film, a superconducting thin film, and a method for producing the superconducting thin film according to the invention will be described with reference to examples, but the invention is not limited to these examples.

In the superconducting thin film according to examples and comparative examples of the invention, a tape-shaped Hastelloy base plate was prepared as a substrate, and surface polishing was performed with respect to one surface of the Hastelloy base plate by mechanical polishing or electric field polishing.

In addition, a bed layer having a thickness of 20 to 120 nm was formed on the surface-polished Hastelloy base plate by using a sputtering device while a material was changed for each of the examples and comparative examples. In addition, 1 to 20 nm of a forcibly-oriented layer (IBAD-MgO layer) formed from MgO was formed on the bed layer by an IBAD method at a normal temperature. 200 nm of an LMO layer formed from LMO was formed on the forcibly-oriented layer by a sputtering method. 200 nm of a cap layer formed from CeO₂ was formed on the LMO layer by the sputtering method at 650° C. A superconducting layer with a thickness of 1 μm formed from YBCO was formed on the cap layer by an MOCVD method at 845° C. to obtain a superconducting thin film (superconducting wire).

### Examples

In respective examples of superconducting thin films, specifically, the material of the bed layer was set to MgAl₂O₄ in Example, the material of the bed layer was set to MgCr₂O₄ in Example 2, the material of the bed layer was set to MgY₂O₄ in Example 3, the material of the bed layer was set to MgLa₂O₄ in Example 4, and the material of the bed layer was set to MgGd₂O₄ in Example 5.

### Comparative Examples

In respective comparative examples of superconducting thin film, specifically, the bed layer was not formed in Comparative Example 1, and the material of the bed layer was set to GZO in Comparative Example 2. The material of the bed layer was set to Y₂O₃ in Comparative Example 3, and the material of the bed layer was set to Al₂O₃ in Comparative Example 4. In addition, the bed layer was set to have a two-layer structure of Y₂O₃ and Al₂O₃ in Comparative Example 5, and the bed layer was set to have a two-layer structure of Y₂O₃ containing Zr—O, and Al₂O₃ in Comparative Example 6.

<Evaluation Method>

Hereinafter, the evaluation method and evaluation result of each of the superconducting thin films produced in Examples 1 to 5, and Comparative Examples 1 to 6 will be described.

(1) Orientation

Calculation of an orientation rate was performed with respect to the superconducting layer of the superconducting thin film according to each of the examples and comparative examples using an X-ray diffraction device (product name: RINT-ULTIMAIII, manufactured by Rigaku Corporation). Specifically, in the X-ray diffraction device, measurement was performed under conditions in which CuKα ray was used, a tube voltage was set to 40 kV, a tube current was set to 40 mA, a scanning speed was set to 2.0 deg/min, a light receiving slit was set to 0.15 mm, and 2θ as a scanning range was set to 5 to 135° to obtain an X-ray diffraction pattern for each superconducting wire material. From the diffraction pattern that was obtained, the orientation rate was obtained using the following expression.

Orientation rate=[Peak intensity of YBCO (006)]/[Peak intensity of YBCO (006)+Peak intensity of YBCO (200)]

(2) Electrical Conduction Characteristics

The electrical conduction characteristics were evaluated by measuring a critical current Ic of each of the superconducting thin films (line width was 10 mm) that were obtained. The critical current Ic was measured using a four-terminal method in a state in which the superconducting thin film was immersed in liquid nitrogen. A voltage terminal was set to 1 cm, and an electric field reference was set to 1 μV/cm.

<Evaluation Results>

Results, which were obtained by performing evaluation with respect to the superconducting thin films according to the respective examples and comparative examples by the above-described evaluation methods, are shown in Table 1.

TABLE 1

| | | | Total | | |
|---|---|---|---|---|---|
| | | | thickness | | |
| | | | of bed | Orientation of | |
| | | | layer | superconducting | |
| | | Structure | (nm) | layer | Ic |
| Examples | 1 | YBCO/CeO₂/LMO/MgO/MgAl₂O₄/base | 20 | A | A |
| | | plate | | | |
| | 2 | YBCO/CeO₂/LMO/MgO/MgCr₂O₄/base | 20 | A | A |
| | | plate | | | |
| | 3 | YBCO/CeO₂/LMO/MgO/MgY₂O₄/base | 20 | A | A |
| | | plate | | | |
| | 4 | YBCO/CeO₂/LMO/MgO/MgLa₂O₄/base | 20 | A | A |
| | | plate | | | |
| | 5 | YBCO/CeO₂/LMO/MgO/MgGd₂O₄/base | 20 | A | A |
| | | plate | | | |
| Comparative | 1 | YBCO/CeO₂/LMO/MgO/base plate | — | C | C |
| Examples | 2 | YBCO/CeO₂/LMO/MgO/GZO/base plate | 50 | B | B |
| | 3 | YBCO/CeO₂/LMO/MgO/Y₂O₃/base plate | 20 | B | C |
| | 4 | YBCO/CeO₂/LMO/MgO/Al₂O₃/base plate | 100 | C | C |
| | 5 | YBCO/CeO₂/LMO/MgO/Y₂O₃/Al₂O₃/base | 120 | B | B |
| | | plate | | | |
| | 6 | YBCO/CeO₂/LMO/MgO/ZrO—Y₂O₃/ | 120 | B | B |
| | | Al₂O₃/base plate | | | |

In addition, in Table 1, a case in which the critical current Ic is 250 A or more is indicated by “A”, a case in which the critical current Ic is equal to or larger than 180 A and less than 250 A is indicated by “B”, and a case in which the critical current Ic is less than 180 A is indicated by “C”. In addition, a case in which the orientation rate is 95% or more is indicated by “A”, a case in which the orientation rate is equal to or larger than 80% and less than 95% is indicated by “B”, and a case in which the orientation rate is less than 80% is indicated by “C”.

From the above-described results, as shown in Table 1, it can be seen that in Examples 1 to 5, the material of the bed layer is set to a spinel compound such as MgAl₂O₄, and thus a superconducting thin film, in which the orientation of the superconducting layer is higher and the critical current Ic is larger than Comparative Examples 1 to 6, may be obtained. This is considered to be because due to the crystal stability of the spinel type crystal structure, while a reaction with the rock salt type compound is suppressed, an effect of suppressing diffusion of metal elements from the substrate is high, and the orientation of the forcibly-oriented layer can be improved.
Reference numeral 1 represents a superconducting thin film.
Reference numeral 2 represents a base material for a superconducting thin film.
Reference numeral 10 represents a substrate.
Reference numeral 22 represents a bed layer.
Reference numeral 24 represents a forcibly-oriented layer.
Reference numeral 30 represents a superconducting layer.

1. A base material for a superconducting thin film, the base material comprising:
a substrate comprising a metal element;
a bed layer formed on a surface of the substrate, the bed layer comprising, as a main component, a non-orientated spinel compound having a spinel type crystal structure and comprising a transition metal element or Al, a metal A, and oxygen; and
a forcibly-oriented layer formed on a surface of the bed layer, the forcibly-oriented layer having biaxial orientation and comprising, as a main component, a rock salt type compound having a rock salt type crystal structure and comprising a metal B,
wherein the metal A and the metal B are both Mg or both Ba.

2. (canceled)

3. The base material according to claim 1, wherein the spinel compound is at least one of MgAl₂O₄, MgCr₂O₄, MgY₂O₄, MgLa₂O₄, or MgGd₂O₄.

4. The base material according to claim 1, wherein a thickness of the bed layer is from 10 nm to 500 nm.

5. The base material according to claim 1, wherein the metal element of the substrate is Ni or Fe.

6. A superconducting thin film, comprising:
the base material according to claim 1; and
a superconducting layer formed on a surface of the forcibly-oriented layer of the base material and comprising an oxide superconductor.

7. A method for producing a base material for a superconducting thin film, the method comprising:
forming a bed layer on a surface of a substrate comprising a metal element, the bed layer comprising a non-orientated spinel compound having a spinel type crystal structure and comprising a transition metal or Al, a metal A, and oxygen; and
forming a forcibly-oriented layer on a surface of the bed layer by an ion beam assisted method, the forcibly-oriented layer having biaxial orientation and comprising, as a main component, a rock salt type compound having a rock salt type crystal structure and comprising a metal B,
wherein the metal A and the metal B are both Mg or both Ba.

8. (canceled)

9. The base material according to claim 1, wherein the metal A and the metal B are both Mg.

10. The base material according to claim 1, wherein the metal A and the metal B are both Ba.

11. The base material according to claim 10, wherein the spinel compound is BaAl₂O₄.

12. The method according to claim 7, wherein the metal A and the metal B are both Mg.

13. The method according to claim 7, wherein the metal A and the metal B are both Ba.

14. The method according to claim 12, wherein the spinel compound is at least one of MgAl₂O₄, MgCr₂O₄, MgY₂O₄, MgLa₂O₄, or MgGd₂O₄.

15. The method according to claim 13, wherein the spinel compound is BaAl₂O₄.

16. The method according to claim 7, wherein a thickness of the bed layer is from 10 nm to 500 nm.

17. The method according the claim 7, wherein the metal element of the substrate is Ni or Fe.
